(19) United States
(12) Patent Application Publication
(10) Pub. No.: US 2011/0287227 A1
(43) Pub. Date: Nov. 24, 2011

(54) METHOD FOR PRODUCING A METAL-OXIDE-COATED WORKPIECE SURFACE WITH PREDETERMINABLE HYDROPHOBIC BEHAVIOUR

(76) Inventor: Eva Maria Moser, Lohningen (CH)

(21) Appl. No.: 12/672,754

(22) PCT Filed: May 30, 2008
(86) PCT No.: PCT/CH08/00244

§ 371 Date: Feb. 9, 2010

(30) Foreign Application Priority Data
Aug. 13, 2007 (CH) 1272/07

(51) Int. Cl. B32B 33/00; C23C 16/02; C23F 1/00; B32B 3/30; B32B 5/16; C23C 16/40; C23C 16/50; B82Y 40/00

(52) U.S. Cl. 428/164; 427/576; 216/37; 977/891

(57) ABSTRACT

It is proposed to produce a workpiece (10) with a metal-oxide-coated surface (9) with a selectable degree of hydrophobic behaviour, by the surface of a substrate material (1) being provided at least in partial regions with a microstructure (2, 3) by mechanical embossing and subsequently being coated. The microstructuring is followed by depositing a hydrocarbon- or silicon-dioxide-containing protective layer (6) and/or at least one top layer (7), on the surface (9) of which the desired hydrophobic properties occur. The sterilizing and catalytic effect of the metal-oxide-containing top layer (7) is enhanced or produced by incorporation of metal-containing nanoparticles.

### FIELD AND BACKGROUND OF THE INVENTION

The invention relates to a method for the production of a metal oxide-coated workpiece surface with predeterminable hydrophobic behavior, with a water contact angle (WCA) greater than 90° and a workpiece surface exerting germicidal action on germs such bacteria, viruses, fungi and microbes, as well as to a workpiece according to the preambles of claims 22 and 23.

The production of ceramic thin films such as metal oxides SiOₓ, AlOₓ, ZnOₓ, ITO, TiOₓ and their hydroxide-containing compounds on diverse materials is industrially realized using various PVD (Physical Vapor Deposition), CVD (Chemical Vapor Deposition) and PE-CVD (Plasma Enhanced Chemical Vapor Deposition) methods and is described in numerous technical works such as in “Traité des matériaux”, 4. Analyse et technologie des surfaces; Hans Jörg Mathieu, Erich Bergmann, René Gras; 2003; ISBN 2-88074-454-7.

Also known is the secondary formation of carbonates on the metal oxide surfaces as a consequence of reactions with the ambient environment. The germicidal, detoxifying and self-cleaning action of a photocatalytically active, hydrophilic titanium dioxide surface is described in numerous publications and is ascribed to the redox reactions in the band gap of the semiconductor titanium dioxide induced by light exposure. In the review by O. Carp, C. L. Huisman, A. Reller, Prog. Solid State Chem. 2004, Vol. 32, No. 1-2, pp. 3-177 the production methods as well as the three application fields (generation of electricity in solar cells, generation as well as destruction of specific substances due to chemical reactions, and photo-induced superhydrophily) are compiled. Exclusively titanium dioxide surfaces with hydrophilic behavior have until now been described in the literature.

Also known is the germicidal (disinfecting, antimicrobial, bactericidal, virucidal, fungicidal) action of workpiece surfaces which are coated with silver or other metals. As prior art for the silver coating of textiles, reference is made to the article by H. J. Lee, S. Y. Yeo and S. H. Jeong in Journal of Material Science 2003, Vol. 38, No. 10, pp. 2199-2204, for the colloidal silver coating of titanium dioxide particles to the article by J. Keleher, J. Bashant, N. Heldt, L. Johnson, Y. Li in World Journal of Microbiology and Biotechnology 2002, Vol. 10, No. 2, pp. 133-139 and for the photolytic silver coating of titanium dioxide, to the article by Mitsuyoshi Machida, Keiichiro Norimoto, Tamon Kumura in Journal of the American Ceramic Society 2005, 88 (1), 95-100. The wetting behavior of liquids—such as in particular of water—on material surfaces plays an important role in many applications. By wetting is understood the degree of the adhering contact of liquids on surfaces, in particular on solid bodies. It denotes the capability of liquids of spreading on a surface. An important case is herein the hydrophobic behavior of a surface, thus the water-repellent behavior, in which the water is repelled at the surface and thereby, for example, drops form. Surfaces are denoted as non-wettable, thus hydrophobic, if the contact angle is >90°. In contrast thereto is the hydrophilic behavior, whereby water is well accepted on the surface. This wetting behavior is measured and defined by the so-called water contact angle (WCA). The better the wettability, the smaller is the contact angle occurring in the wetting and is <90°. The definition is found in the review by Huan Liu, Jin Zhai and Lei Jiang, Soft Matter, 2006, 2, 811-821.

Ceramic, metal oxide-containing surfaces are hydrophilic. One of the disadvantages of a hydrophilic surface is the drop formation of liquids. The workpiece surface is therefore moist for a long time and does not dry off. This condensation behavior can also prevent the removal of liquids and contaminants as well as the problem-free cleaning of the surface. As a consequence thereof, liquids and bulk goods cannot be transferred without leaving residues and the growth of germs as well as the corrosion in metals are fostered.

### SUMMARY OF THE INVENTION

The present invention addresses the problem of eliminating the disadvantages of prior art. The problem addressed by the present invention is, in particular, realizing a method which makes feasible treating material surfaces comprised of synthetic material, natural materials, and metals in such manner that a metal oxide-containing coated workpiece surface with a desired degree of hydrophobic, germicidally acting behavior is formed. The present invention, additionally, addresses the problem of being able to utilize already known and proven basic processes which permit the economic manufacture of the product.

Through the implantation of metal-containing nanoparticles on the surface of the metal oxide cover layer a germicidal and, if indicated anti-static, protective effect is attained. The plasma method utilized according to the invention for the production of the nanoparticles permits the extensive immobilization of the nanoparticles and therewith the control of the dosing of the release of the metal ions and the minimization of the risk of mobile nanoparticles. The germicidal action of the metal ions—which takes place without light exposure—is of great significance in particular in the field of medicine.

In the special case of ceramic thin film titanium dioxide—especially in the presence of the anatas modification—the germicidal action due to the photocatalytic activity under light exposure is also available without the release of metal ions. Through the implantation of metal particles in catalytic thin film systems, on the one hand, the catalytic activity and electric conductivity is significantly increased, on the other hand, the germicidal action of the workpiece surface takes place independently of exposure to light.

In all variants hydrophobic behavior is forced onto the inherently hydrophilic metal oxide surface by microstructuring the workpiece surface. The changed condensation behavior effects a better transfer of liquids and bulk materials as well as better cleaning and drying of the workpiece surface.

In the second variant the hydrophobic effect is somewhat reduced through the presence of a nanostructuring, on the other hand, however, the catalytic activity of the titanium dioxide or zinc oxide layer is enhanced, which is of advantage for certain applications. The result in any case is an actively germicidal, detoxifying and self-cleaning workpiece surface which is of significance in particular in the medical and pharmaceutical field. Through the combination of the up to three synergistically acting modifications (microstructure, metal-containing nanoparticles, titanium dioxide) a durable, sustained and actively self-cleaning, germicidal workpiece surface is obtained. Adjustment of these combination elements is decisive for the particular application in order to attain an optimal effect.

This problem is resolved according to the invention through the characteristics of claims 1, 2, 3, 22 and 23. Further advantageous embodiments are found in the dependent patent claims. According to the invention, a workpiece is to be coated with a metal oxide-containing thin film, the hydrophobic and germicidal behavior of which is to be of a selectable degree. The surface of a substrate material is therefore provided, at least in subregions, with a microstructure through mechanical embossing and is subsequently coated. For the generation of the microstructure the workpiece is to be comprised of an embossable material, such as for example of a polymer, preferably a thermoplastic resin such as, for example polypropylene or a metal, preferably a ductile metal, such as copper, aluminum, steel and their alloys. In the case of a metal other methods such as shot blasting or electro-corrosion can also be employed.

The plasma treatment takes preferably place in a closed system, in which the introduced process gases are pumped down using a vacuum pump. The particular working pressure range is settable within a broad range and can attain atmospheric pressure. The different processes permit the specific and selective preparation of surfaces with the desired degree of wettability.

For the generation of a workpiece surface with predeterminable hydrophobic behavior with a water contact angle (WCA) greater than 90°, according to the invention in the first variant the following method steps are performed:
a substrate is utilized into which, at least in subregions, is mechanically embossed a line-like or grid-like microstructure with indentations and elevations, which microstructure is formed of a multiplicity of contiguous structure elements, whose individual extents are in the range of 3 μm to 50 μm, and that between the adjoining structure elements trough-shaped indentation or elevations with a depth in the range from 1 μm to 10 μm, preferably 3 μm to 7 μm, are formed, which are disposed about the structure elements with a width in the range from 3 μm to 11 μm, preferably 5 μm to 7 μm;
after the microstructuring at least one final coating is deposited, at least in subregions, onto the substrate in a vacuum chamber out of a plasma discharge, which plasma discharge contains at least one metal-containing and one oxygen-containing gas and/or a metal oxide-containing compound, which coating has a layer thickness in the range of 5.0 to 500 nm, preferably 10 to 300 nm.

For the generation of a polymeric workpiece surface with predeterminable hydrophobic behavior with a water contact angle (WCA) greater than 90° as well as a workpiece surface with germicidal action, according to the invention, in the second variant the following method steps are performed:
a substrate is utilized which is, at least on the surface, comprised of synthetic material and into this synthetic surface, at least in subregions, a line-like or grid-like microstructure with indentations or elevations is mechanically embossed, which microstructure is formed of a multiplicity of contiguous structure elements, whose individual extents are in the range of 3 μm to 50 μm, and that between the adjoining structure elements trough-shaped indentation or elevations with a depth in the range of 1 μm to 10 μm, preferably 3 μm to 7 μm, are formed, which are disposed about the structure elements with a width in the range from 3 μm to 11 μm, preferably 5 μm to 7 μm;
after the mechanical structuring the substrate is treated, at least in subregions, in a vacuum chamber in at least two steps with a plasma discharge, wherein in a first step to the plasma at least oxygen or hydrogen is supplied for the chemical etching of the substrate surface and, in the succeeding second step, to the plasma at least one inert gas is added for the ion etching of the substrate surface;
after the plasma treatment a hydrocarbon-containing or silicon oxide-containing protective layer is deposited in a vacuum chamber out of a plasma discharge onto the substrate, at least in subregions, to which plasma discharge is supplied at least one hydrocarbon-containing or at least one silicon-containing and oxygen-containing gas, and that a layer thickness is generated which is in the range of 2.0 to 70 nm, preferably in the range of 5.0 nm to 30 nm;
in a further step at least one cover layer is deposited in a vacuum chamber out of a plasma discharge, at least in subregions, onto the substrate, which plasma discharge contains at least one metal-containing and one oxygen-containing gas and/or a metal oxide-containing compound and has a layer thickness in the range of 5.0 to 100 nm, preferably 10 to 50 nm.

For the generation of a workpiece surface with predeterminable hydrophobic behavior with a water contact angle (WCA) greater than 90° as well as a workpiece surface with germicidal action, according to the invention in the third variant the following method steps are performed:
a substrate is utilized into which, at least in subregions, a line-like or grid-like microstructure with indentations or elevations is mechanically embossed, which microstructure is formed of a multiplicity of contiguous structure elements, whose individual extents are in the range from 3 μm to 50 μm, and that between the adjoining structure elements trough-shaped indentation or elevations with a depth in the range of 1 μm to 10 μm, preferably 3 μm to 7 μm, are formed, which are disposed about the structure elements with a width in the range of 3 μm to 11 μm, preferably 5 μm to 7 μm;
after the mechanical structuring a hydrocarbon-containing or silicon oxide-containing protective layer is deposited in a vacuum chamber out of a plasma discharge onto the substrate at least in subregions, to which plasma discharge at least one hydrocarbon-containing or at least one silicon- and oxide-containing gas is supplied, and that a layer thickness is generated which is in the range of 2.0 nm to 500 nm, preferably in the range of 5.0 nm to 100 nm;
in a further step at least a cover layer is deposited in a vacuum chamber out of a plasma discharge, at least in subregions, onto the substrate, to which plasma discharge is supplied a metal-containing and oxygen-containing gas and/or a metal oxide-containing compound, and that a layer thickness is generated which is in the range of 5.0 to 500 nm, preferably in the range of 10 nm to 300 nm,
in a further step at least one type of metal-containing nanoparticles are deposited in a vacuum chamber out of a plasma discharge, at least in subregions, onto the substrate, to which plasma discharge is supplied at least one metal-containing gas, and that these nanoparticles have a particle size of 1.0 to 70 nm diameter, preferably 3.0 to 20 nm.

The substrate can be of an organic nature (polymer-like or natural materials) or of an inorganic nature (metals, alloys, ceramic, glass, etc.) or be comprised of a combination thereof. As polymers are preferably utilized thermoplastic resins, among the natural materials are conceivable objects of paper, corn starch, cotton or viscose. In the case of inorganic materials are preferably involved metallic substrate surfaces. Conceivable are in particular readily deformable substrates such as aluminum foils, workpieces coated with metal, etc. The substrates can be two- or three-dimensional objects, such as a foils and films, plates, fabrics, membranes, textiles, threads, rolls, tubes, housing, bottles, containers, etc. The microstructure is advantageously mechanically embossed into the substrate material on its surface. Etching methods, for example electrochemical, electrocorrosive or chemical methods, are also feasible, however, they are to some extent less economical. The mechanical embossing can be carried out in known manner, for example using force presses or rollers. For synthetic substrates hot embossing is suitable. Structuring advantageously takes place with periodically repeating identical structure elements, advantageously is formed line-like or grid-like and should at least take place in subregions on a substrate surface. Especially suitable as synthetic materials are thermoplastic resins and preferably polypropylene.

The hydrocarbon-containing protective layer serves to promote adhesion and/or as a diffusion barrier as well as for corrosion protection of metallic surfaces when inserting metal-containing nanoparticles. Very generally, the protective layer protects against ambient effects and permits the stable behavior of the surface, such that degradations through the catalytic action of the final layer or corrosion of the substrate are substantially avoided over several months to years or can at least be kept extremely low. The layer thickness of the hydrocarbon-containing or silicon oxide-containing protective layer is 2.0 nm to 200 nm, preferably 5.0 nm to 100 nm, and, in the case of transparent colorless coatings, 5.0 nm to 50 nm.

The corrosion of the metallic substrate surface is additionally prevented, on the one hand, through the diffusion barrier of the protective layer, on the other hand, through the implantation of at least one type of metal-containing nanoparticles of 5.0 at % to 50 at %, preferably of 5.0 at % to 20 at % thereby that the electrochemical potential of the metallic substrate is modified. This cathodic or anodic protection through metal-containing nanoparticles is described in the European Patent EP 1 251 975 B1. Through the combination with the hydrophobic behavior of the coated surface, the workpiece surface dries faster. As a consequence thereof, the corrosion protection is additionally increased. The metal oxide-containing cover layer can additionally lend scratch protection to the workpiece.

Through the implantation of metal-containing nanoparticles the electric conductivity on the metal oxide-containing surface can be increased; in an insulating workpiece the antistatic effect is thereby generated.

In the three embodiments according to the invention it is feasible to carry out between the substrate surface, the protective layer, and the cover layer, further process steps or coatings, provided the microstructure and, if indicated, the nanostructure are effectively represented on the workpiece surface. It is understood that for these process steps any desired methods can be employed. If indicated, the hydrophobic effect can be enhanced with a rough workpiece surface, such as is described in the paper by S. Shibuichi et al., Journal of Colloid and Interface Science 208, 287-294 (1998).

Added to this is the fact that all of the described treatments of the substrate (1) can be carried out over the entire surface or only in areal subregions.

The various features of novelty which characterize the invention are pointed out with particularity in the claims annexed to and forming a part of this disclosure and are entirely based on the Swiss priority application no. 1272/07 filed Aug. 13, 2007, and International Patent Application PCT/CH2008/000244 filed May 30, 2008, which is incorporated here by reference.

### BRIEF DESCRIPTION OF THE DRAWINGS

In the following the invention will be explained by example and in conjunction with schematic Figures:

FIG. 1 a schematic depiction of a production device for the manufacture of a workpiece surface with hydrophobic behavior;

FIG. 2 in cross section a substrate with microstructured surface for the implementation according to the invention;

FIG. 3 in cross section the substrate according to FIG. 2 with superimposed nanostructured surface;

FIG. 4 in cross section the substrate according to FIG. 3 with a protective layer on the micro- and nanostructured area;

FIG. 5 in cross section the substrate according to FIG. 4 with cover layer deposited on the protective layer, the workpiece surface with hydrophobic behavior;

FIG. 6 an example of the layer build-up with nanostructuring on a substrate surface of synthetic material;

FIG. 7a in cross section a substrate with microstructured surface and with hydrocarbon-containing protective layer deposited thereon, which comprises metal-containing nanoparticles and a cover layer with embedded nanoparticles for the third version of an embodiment according to the invention;

FIG. 7b an enlarged segment from FIG. 7a;

FIG. 8 in top view a depiction of a microstructured substrate surface with structure elements of different sizes and different shapes, which can represent indentations or elevations;

FIG. 9 in top view an example of a microstructured substrate surface with square structure elements of equal size and offset with respect to one another, which can represent indentations or elevations;

FIG. 10 in top view a further example of a microstructured substrate surface with pyramidal structure elements of equal size and not offset with respect to one another, which can represent indentations or elevations;

FIG. 11 in top view a further example of a microstructured substrate surface with polygonal structure elements which can represent indentations or elevations;

FIG. 12 in top view an example of a nanostructured substrate surface.

### DESCRIPTION OF THE PREFERRED EMBODIMENTS

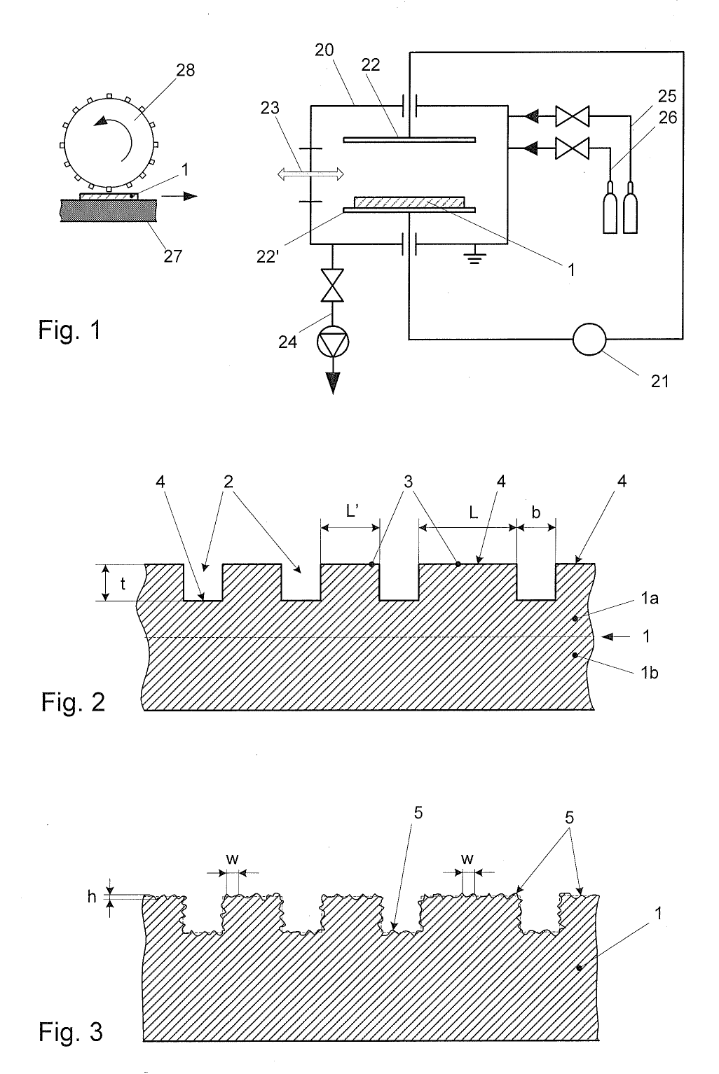

For the production of a workpiece 10 with the desired degree of hydrophobic behavior, first, the substrate 1 on its surface is provided with a microstructure, preferably through mechanical embossing, and subsequently plasma-treated and/or coated in a vacuum unit 20, as is shown schematically in FIG. 1. The embossing is carried out employing known methods thereby that into the substrate surface 4 of the substrate 1 located on a substrate carrier 27 the intended structure elements 3 are embossed or pressed using an embossing tool 28, such as an embossing die or an embossing roller.

Band-shaped substrates, for example metal foils, can advantageously also be worked using continuous methods. The further working steps are subsequently carried out in a vacuum unit 20. The substrate 1 is transported into the vacuum unit 20 through a vacuum lock 23 and here placed onto a carrier or directly onto an electrode 22′. The vacuum unit is evacuated via a pump system 24. The working gas and, if desired, a carrier gas, such as preferably inert gases, such as for example argon or helium, are introduced via gas inlet systems 25, 26 into the vacuum chamber with the desired gas flow and working pressure in the chamber. A second electrode 22 is disposed opposite the first electrode 22′ and both electrodes are connected to a power supply 21 for generating the plasma. The plasma discharge can be fed in individual method steps with a DC power supply 21, provided materials are involved which have at least a certain electric conductivity. For materials that are lower conducting material or for dielectric materials, such as synthetic materials, DC-pulsed feeds or AC feeds 21 are advantageously employed. The value of the DC-pulse frequency or of the AC frequency is selected depending on the thickness and conductivity of the materials involved in the process. In the case of DC pulses advantageously frequencies of 50 kHz to 500 kHz can be employed with unipolar as well as also bipolar pulses. Bipolar pulses can be asymmetric and only have a small negative or positive component, wherein the switch-on time should be greater than the switch-off time. For the AC feed center frequencies of 10 kHz to 1.0 MHz can be utilized. Often utilized frequencies for the AC feed are in the RF range, which encompasses a range of 1.0 MHz to approximately 1.0 Ghz. In certain cases the use of microwaves is also feasible, with frequencies above 1.0 Ghz. If indicated, it is advantageous to utilize magnetic-field enhanced plasma reactors.

Further coating sources, such as sputtering sources, preferably magnetron sources, can be provided in order to be able to develop also additional layers with methods other than the cited plasma deposition (PECVD). For metal oxide-containing layers, such as for example TiOₓ herein preferably a reactive process is employed, in which the material to be sputtered comprises titanium and oxygen as the working gas 26 and a carrier gas 25, for example argon, is introduced into the process chamber 20. The sputtering sources are also operated with DC or AC feeds, according to the aforementioned specifications. The individual steps of the vacuum processes can also be carried out in several units, they are, however, advantageously all carried out in the same unit or in multi-chamber systems if different process conditions are necessary or also full automation is provided.

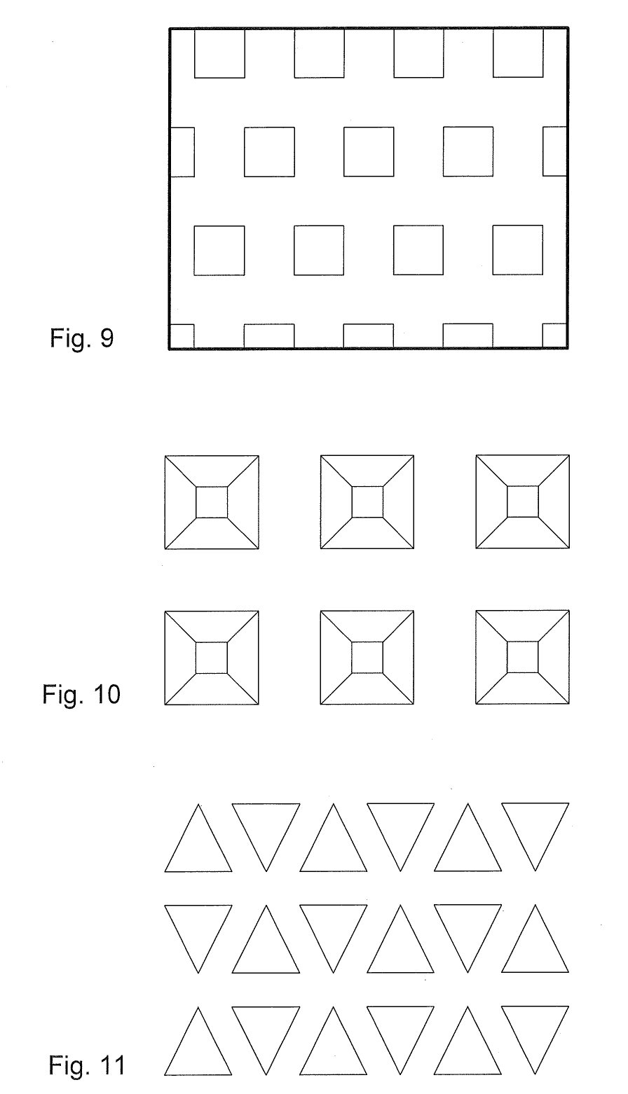

In conjunction with FIGS. 2 to 6 in the following the individual steps for the generation of a workpiece 10 for the first variant of the invention will be described. In the second variant a nanostructure 5 is developed directly from a synthetic material substrate surface and superimposed on a microstructure 2, 3 on the substrate surface 4. FIG. 2 depicts schematically and in cross section, and FIG. 8 in top view, the manner in which in a first step (a) a microstructure is mechanically embossed into the surface of the substrate 1 in order to obtain, at least in subregions, a microstructured surface 4. The substrate 1 can herein be comprised of several different materials. The substrate 1 includes, for example in the lower region, a different material 1b than in the upper region 1a, which borders on the substrate surface. The upper portion is comprised of a polymer or metal 1a and is that material portion into which the microstructure 2, 3 is embossed. As synthetic materials are suitable thermoplastic resins, in particular polyolefins. The microstructure is comprised of a line-like or grid-like structure with mechanically embossed indentations or elevations 2, which is formed of a multiplicity of contiguous structure elements 3, the individual extents L, L′ of which are in the range of 3 μm to 50 μm. Between the adjoining structure elements 3 are formed the indentations or elevations 2 in the shape of troughs. These indentations or elevations 2 can also have interruptions in the circumference. The lines furthermore do not need to be straight but can also have a zigzag or curved shape.

The depth t of the trough-shaped indentations or elevations 2 is in the range of 1 μm to 10 μm, preferably 3 μm to 7 μm. The indentations or elevations can be embossed differently in a workpiece. The cross sectional form of the indentations or elevations 2 is not especially important and can be selected according to practical considerations of production techniques.

The width b of the trough-shaped indentations or elevations 2 on the substrate surface 4 is in the range of 3 μm to 11 μm, preferably of 5 μm to 7 μm. The dimensions 1, 1′ of the structure elements 3, thus the longest extent 1 and the shortest extent 1′ of the area of the structure element, is within the range of 3 μm to 50 μm.

The structure elements can have various shapes and sizes, such as is depicted in FIGS. 2 and 8. For the practical realization periodically repeating patterns are of advantage, such as are depicted for example in the schematic FIGS. 9 to 11 in top view. FIG. 9 shows a microstructure with periodically disposed rectangular or square structure elements 3 with a disposition offset with respect to one another in a line.

FIG. 10 depicts an example with square structure elements 3 in non-offset disposition and FIG. 11 a microstructure with periodically disposed polygonal structure elements 3. The gap width is 3 to 7 μm, preferably about 5 μm. Based on the Figures it is evident that width b of the indentations or elevations 2 is always smaller than the extent 1, 1′ of the adjacent structure elements 3.

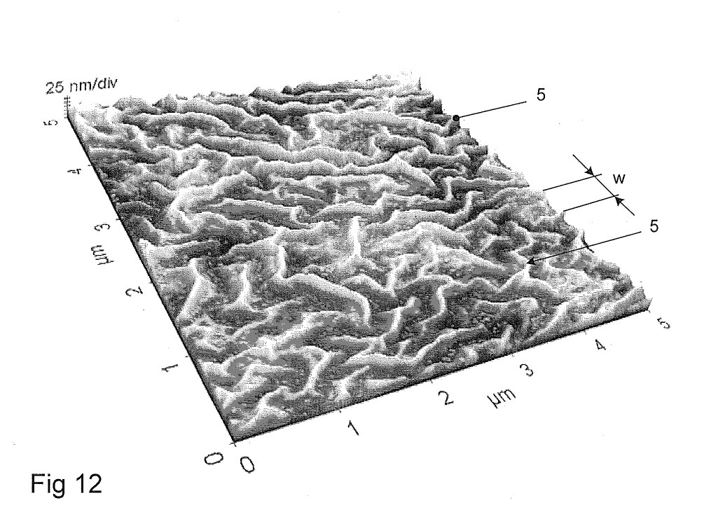

In the second variant in the next, the second step, the generation of a nanostructure 5 takes place, which is superimposed directly onto the microstructure at least in subregions and from the surface 4 of synthetic material, here from the substrate surface of synthetic material, with an at least two-stage plasma treatment, as is depicted in FIG. 3 in cross section. In FIG. 12 is shown as an example a nanostructured surface 5, 5′ with statistically distributed worm-like structures, such as result from this method. The nanostructure 5 is here developed such that the height h of their elevations is set in the range of 20 nm to 120 nm and the distances or the extent w of the elevations are in the range of 40 nm to 200 nm. After the mechanical structuring, the substrate 1 is treated in a vacuum chamber 20 in two steps with a plasma discharge, wherein in a first step to the plasma at least oxygen or hydrogen is supplied for the chemical etching of the substrate surface 4 and, in the succeeding second step, to the plasma at least one inert gas, preferably argon, is added for the ion etching of the substrate surface 4. Through the length of the process control and the setting of the process parameters the aforementioned values to be achieved can be selected. Further process steps can take place before the first step or between the two steps or subsequent to them if this is required, for example for cleaning the surfaces, such as for example that of the substrate. For the substrate cleaning, after the coarse cleaning and fine cleaning, preferably a plasma process is utilized for the extremely fine cleaning, in which an inert gas such as argon or an etching working gas, such as oxygen or hydrogen, is supplied. Other methods for cleaning, such as ion etching are also feasible.

In the case of a metal substrate the nanostructure can also be carried out through a suitable plasma process or with the anodic oxidation of metal-containing surfaces, such as are described in the publication by S. Shibuichi, T. Yamamoto, T. Onda and K. Tsujii, Journal of Colloid and Interface Science 208, 287-294 (1998).

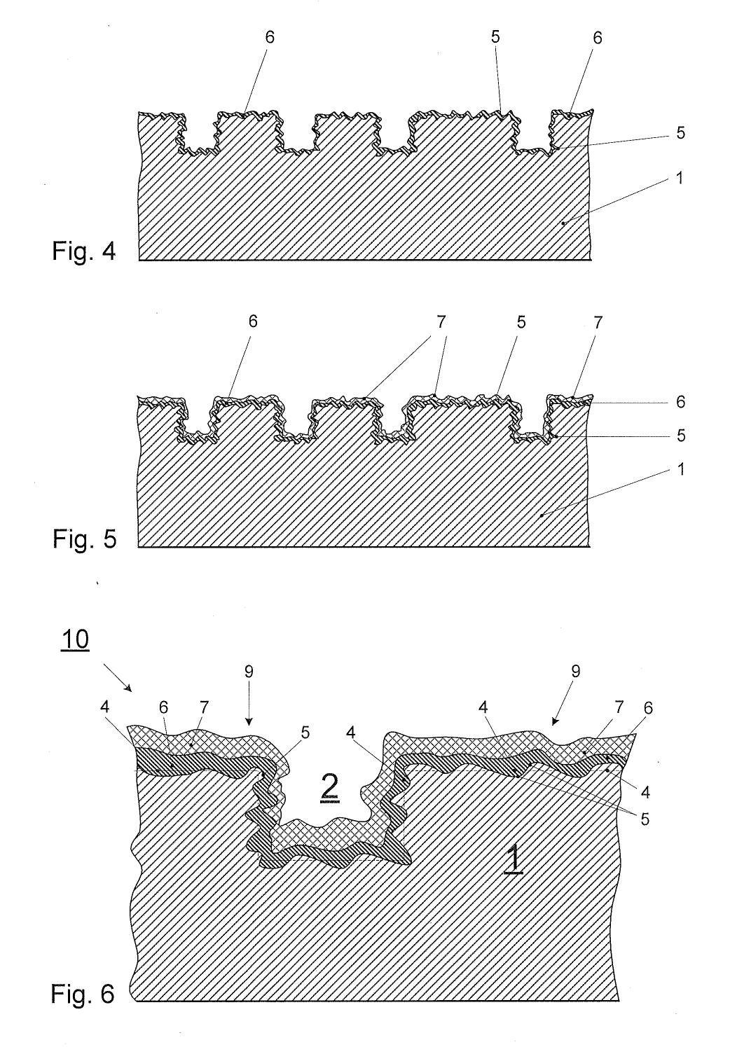

In variants two and three in a next step, at least in subregions, a hydrocarbon-containing and/or silicon oxide-containing protective layer 6 is deposited in a vacuum chamber 20 out of a plasma discharge onto the substrate 1, as is depicted in FIG. 4. For this purpose to the plasma a hydrocarbon-containing and/or silicon- and oxygen-containing gas is supplied, wherein a layer thickness 6 is generated which is in the range of 2.0 to 500 nm, preferably in the range of 5.0 to 100 nm. In transparent, colorless coatings the layer thickness is 5.0 to 50 nm. With this protective layer 6 the workpiece 10 is protected against undesirable changes through damaging environmental effects. Such a protective layer 6 is with advantage developed as a dense, three-dimensionally highly cross-linked plasma-polymerized backbone which is flexible and soft or is formed as a hard layer, one protected against mechanical damage (scratch protection, etc.).

The protective layer 6 should advantageously lower the permeability of oxygen by at least the factor 10 compared to the uncoated, gas-permeable substrate 1. This is measurable, for example through the plasma coating of a 12 μm thick polyethylene terephthalate film, which should have an oxygen permeability less than 25 ml/m²×day×bar. The plasma-polymerized hydrocarbon-containing protective layer 6 deposited on a metal surface and doped with metal-containing nanoparticles has a corrosion-inhibiting effect, which is expressed in the following manner: if the same protective layer is doped with metal-containing particles 11 in order to shift the electrochemical potential of the metal-containing substrate, the corrosion-protecting effect is at least doubled compared to an also coated, non-microstructured substrate.

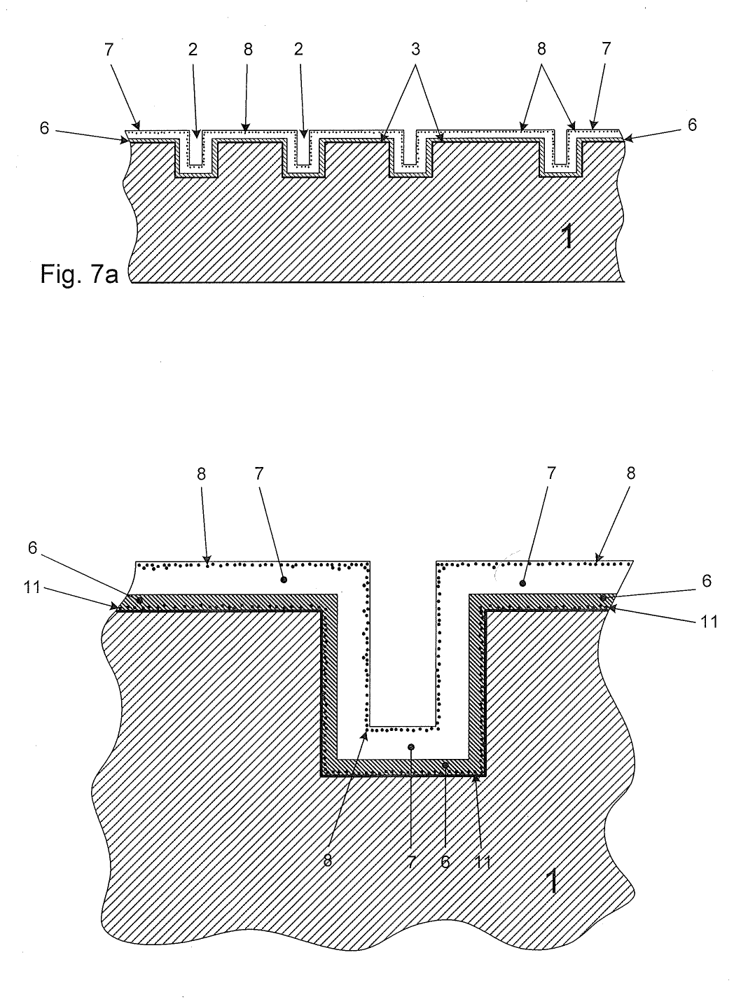

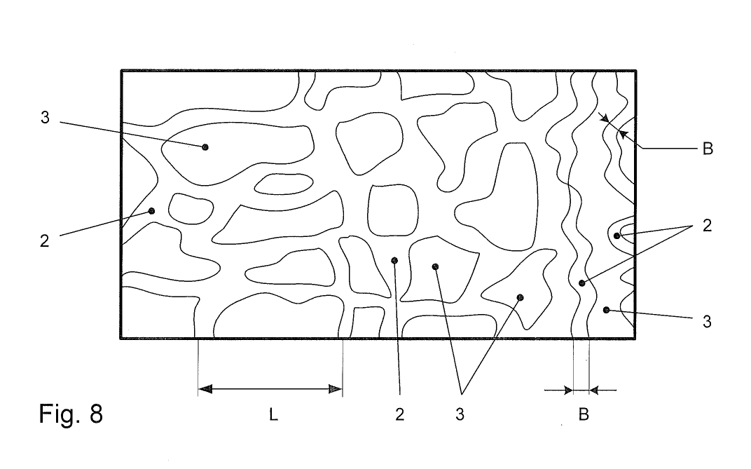

In FIGS. 6, 7a and 7b is depicted the completely treated and coated workpiece 10 enlarged and in cross section with a microstructured substrate surface 2, 3 with superjacent protective layer 6 and a terminating cover layer 7 with the workpiece surface 9. This combination now permits the production of workpiece surfaces 9, which have the arbitrarily settable hydrophobic behavior with a WCA greater than 90°. For most applications a WCA is advantageously set which is in the range of 90° to 160°, preferably in the range of 110° to 160°.

In FIGS. 7a and 7b is depicted enlarged and in cross section the completely treated and coated workpiece 10. The substrate 1 with the microstructured substrate surface 2, 3 with superjacent protective layer 6 with incorporated metal-containing nanoparticles 11 and superjacent cover layer 7 with incorporated metal-containing nanoparticles 8.

According to variant 1 the workpiece 10 is equipped with a ceramic metal oxide-containing thin film with a thickness of 5.0 nm to 500 nm. Depending on the selection of the ceramic cover layer (TiO₂, TiOₓ(OH)_{y}, ZnO, AlOₓ, SiOₓ, ITO((In)SnO₂) and their hydroxides, etc.) the catalytic effect and/or the electric conductivity (inter alia antistatic effect) are increased through the metal-containing nanoparticles 8. Metal-containing nanoparticles 8 (Au, Ag, Pt, Pd, Rh, Cu, Fe, Ti, Zn, etc. or combinations thereof) are incorporated into the outer surface at 5 at % to 50 at %, preferably 5 at % to 20 at %, at the grain limits of the metal oxide-containing surface, in particular into the uppermost atom layers of the cover layer. In the case in which for example gold- or silver-containing nanoparticles are used, which have inherent bactericidal action, the germs are killed through the released metal ions.

According to variant 2, a workpiece 10, at least polymeric on the surface, is provided with a nanostructure in order to increase the catalytic effect of the cover layer (TiO₂, ZnO, etc.), which permits, for example, the detoxification on the workpiece surface. The germs are killed and subsequently decomposed through the photocatalytic redox reactions, ideally into the end products carbon dioxide and water.

If required, in this variant 2 metal-containing nanoparticles can also be embedded on the titanium dioxide surface. For many applications in the pharmaceutical and medical field this is useful in order to be able to attain germicidal action even without light exposure or attain an antistatic effect.

According to variant 3, the workpiece 10 is coated with a catalytically acting metal oxide (TiO₂, ZnO, etc.) and provided on its surface with metal-containing nanoparticles 8. I

n all three variants a titanium oxide-containing cover layer 7 can be deposited with a thickness in the range of 5.0 nm to 500 nm. A photocatalytically active titanium dioxide layer is preferably deposited, which has a self-cleaning, detoxifying surface and which is additionally bio-compatible. If the substrate is an organic substrate (polymer, paper), the protective layer 6 is necessary before the deposition of the titanium oxide-containing cover layer 7 in order to prevent a possible degradation of the substrate. In the case of a metallic substrate the titanium oxide-containing layer can be directly deposited onto the substrate as a protective layer 6. The titanium oxide-containing layer for this self-cleaning function is the uppermost layer in every application. The photocatalytic properties of this titanium oxide-containing cover layer 7 are increased through the surface enlargement of the substrate (micro- and/or nanostructuring). In the presence of the surface, with its hydrophobic property “forced” onto it according to the invention, an organic contamination is not only photocatalytically destroyed but additionally also easily wiped off.

With all coatings it is important, for example through the selection of the layer thickness, to ensure that the microstructure 2, 3, and in particular also the nanostructure 5, is at least still represented on the workpiece surface 9 in order to be able to fulfil the function.

The employment range of workpieces 10 with germicidally acting surfaces 9 is extremely broad. Conceivable is equipping air-conditioning systems, air humidifiers, sanitary installations, swimming pools, textiles and objects of use in hospitals, pharmaceutical packagings, home and household articles, etc.

The combination with the hydrophobic behavior (anti-adhesive effect and, if applicable, also antistatic effect) is important to ensure the maintenance of the surface properties of materials such as protection against contamination (residual contamination), economic and hygienic aspects (capability of emptying of residues in the case of packagings, durability of pharmaceutical packagings such as tubes) and oxide formation of metals (corrosion). The condensation behavior of water, e.g. drop formation of water, is matched to the use of the product through the setting of the hydrophobic behavior properties. For an aluminum-containing surface in a heat exchanger or air humidifier the cleaning maintenance can be considerably lowered through the use of contamination-repellent and/or corrosion-protected surfaces. In processing materials such as metals and their alloys, the anti-adhesion effect reduces the elaborate and complex removal of adhering dirt particles and protects the substrate against corrosion, in particular if nanoparticles 11 at the interface of the protective layer 6 shift the electrochemical potential of the substrate in order to attain a cathodic or anodic active protection.

In this connection the combination of the hydrophobic surface with the diffusion protection is important against the transfer of gases such as oxygen, nitrogen and carbon dioxide as well as a migration protection against undesired additives from the packaging into the contacting environment. A further advantage of working-out the synthetic surfaces, especially polypropylene, according to the invention, is maintaining the sealability of the workpiece. If indicated, the maintenance of the sealability property can be increased by omitting treatment steps in these subregions.

In the following the invention will be explained in conjunction with further examples.

Description of the procedure for the treatment of a polypropylene sheet which, for example, has a thickness of 75 μm. The discrete working steps are listed in Table 1.
First step: with a heatable embossing roller and a rubber roller (hot embossing) the microstructure is embossed into the polypropylene sheet.
Second step: a vacuum chamber is evacuated in order to reach a base pressure of lower than approximately 10′ mbar as the subsequent operating pressure. The working gases are subsequently introduced into the vacuum chamber via mass flow controllers, the operating pressure is checked with a pressure gauge.
In the second variant using a plasma method at ambient temperature a nanostructure is superimposed onto the microstructure, at least in subregions, onto the microstructured substrate.
First process stage: RF plasma, ambient temperature, grounded substrate
   Power range: 200 to 700 Watt, typically at 400 Watt
   Operating pressure: approximately 1.0×10⁻² mbar
   Working gas: 10 to 60 sccm oxygen
   Process time: 10 to 60 sec
Second process stage: RF plasma, ambient temperature, grounded substrate
   Power range: 100 to 600 Watt, typically at 300 Watt
   Operating pressure: approximately 5×10⁻⁴ mbar
   Working gas: 10 to 50 sccm argon
   Process time: 10 to 60 sec
   Process time: 10 to 60 sec
Third step: The workpiece surface enlarged through the structuring is provided with a three-dimensionally highly cross-linked, plasma-polymerized hydrocarbon layer or DLC or a silicon oxide-containing layer. The structuring is thereby fixed and protected against direct contact with the ambient environment.

Example of process conditions: RF plasma, ambient temperature, substrate grounded with or without bias voltage
Power range: 50 to 400 Watt, typically 100 Watt
Operating pressure: 3×10⁻² mbar
Gas mixture: 30 sccm C₂H₂, 15 sccm He
Fourth step: Deposition of a photocatalytically active, titanium dioxide-containing cover layer (comprising anatas) at a substrate temperature of <80° C.

Examples of process conditions: Pulsed, reactive DC magnetron sputter process with grounded substrate and variable magnetic field strength:
Power: 2000 Watt
Working pressure range: 1×10⁻² mbar up to several mbar, typically 5×10⁻² mbar
Gas mixture: 35 sccm argon and 13 sccm oxygen
Fifth step: Deposition of metal-containing silver nanoparticles with a diameter of 3 to 20 nm onto the photocatalytically active titanium oxide-containing cover layer 7 at a substrate temperature of <50° C.

Example of process conditions with a non-moving substrate and without cover screen (shutter): pulsed DC magnetron sputter process with variable magnetic field strength from a silver target and a substrate which is grounded or is provided with a pulsed RF bias voltage (0 to −200 V).
Power: 10 to 50 Watt, with increasing and decreasing ramp of 0.5 sec each and a plateau of 0.1 sec
Process time: 3 times 1.1 sec
Working pressure range: 3×10⁻³ mbar to 3×10⁻² mbar, typically 9×10⁻³ mbar
Gas mixture: 5 to 15 sccm argon and 10 to 50 sccm helium

Preferred for all plasma processes is a working pressure range of 5×10⁻⁴ mbar to several mbar, if applicable, the working pressure can reach 1 atm. The plasma processes are preferably carried out at ambient temperature (substrate can be thermostatted, cooled or minimally heated), the workpiece is grounded or provided with an optional—preferably pulsed—bias voltage. The layer thickness is in each instance varied over the treatment time or the rate of sample transfer.

TABLE 1
Ranges for measured water contact angles of titanium dioxide-containing or DLC-coated
workpiece comprised of polypropylene with different microstructure elements. For the
titanium dioxide-containing, coated, microstructured substrates the values with and without
nanostructures are specified. For the coated, smooth or non-microstructured workpiece surfaces
the water contact angles and the surface energy are compiled.

| | DLC | TiO₂ | TiO₂ | |
|---|---|---|---|---|
| | micro | micro | micro-nano | Description of the Microstructure |
| Sample | WCA [°] | WCA[°] | WCA[°] | p: period, a: distance, d: depth [μm] |
| 1 | 127.3 | 109.4 | 117.5 | Offset squares (elevations) with p: 28, a: 3, d: 5 |
| 2 | 124.2 | 121.2 | 113.9 | Rectangles (elevations) with p: 27, a: 3, d: 5 |
| 3 | v 129/h 109 | v 128.0 | V 114.5 | Lines with p: 28, a: 3, d: 5 (v: vertical, h: horizontal) |
| 4 | 136.7 | 121.3 | 109.6 | Squares (indentations) with p: 20, a: 5, d: 5 |
| 5 | 126.7 | 118.9 | 116.9 | Squares (elevations) with p: 28, a: 3. d: 7 |
| 6 | 130.3 | 117.3 | 110.9 | Triangles (elevations) with p: 25, a: 3.5, d: 5 |
| 7 | 129.1 | 101.8 | 92.9 | Pyramids (indentations) with p: 10, a: 5, d: 2 |
| 8 | 128.6 | 112.6 | 89.9 | Stars (elevations) with p: 28, d: 4.5 |
| Smooth | 97.2 | 81.8 | 44.8 | Surface energy of TiO₂ cover layer = |
| | | | | 37 mN/m, 49 mN/m (nanostructured |

Explanations of the Table: The water contact angles (WCA) were determined with a contact angle measuring instrument, using distilled water as the test liquid, according to ASTM D5725-95 and ASTM D724 at 23° C. and 50% relative humidity.

A microstructured workpiece surface plasma-coated with a DLC or a-C:H or silane-containing a-Si/C:H permits stable hydrophobic behavior with a WCA >90°. This workpiece surface is characterized by a surface energy of <37 mN/m—measured on the smooth workpiece surface-which is stable over a relatively long time period. Without microstructuring the surface has a water contact angle which, depending on the cover layer, is settable within a wide range and which, according to the Table, is in the range of 45° (TiO₂, SiO₂, etc.), wherein the surface energy is in the range of 49 mN/m (TiO₂, SiO₂, etc.).

If a workpiece surface is only provided with the microstructure in subregions, through the combination with the TiO₂ cover layer (7) the following condition can result:
smooth portion: hydrophilic behavior with WCA <90°
microstructured portion: hydrophobic behavior with WCA >90°

Through the combination with the nanostructure the contact angle is significantly lowered, however, in particular on the smooth, non-structured workpiece surface.

A further concrete application of the hydrophobic surface is the prevention of water penetration to the material surface which can have several disadvantageous consequences. Corrosion-causing particles (electrolytes, salts, etc.) can be transported to the surface or boundary surface of the base material and can here react. For the corrosion protection a rapidly drying, hydrophobic surface is of advantage. The surface is thereby also contaminant-repellent. The implantation of metal-containing nanoparticles into the protective layer 6 additionally protects the metallic substrate against corrosion if the electrochemical potential of the substrate is correspondingly modified. A further advantage is that permeating gases and compounds can enter into reactions with these metal-containing nanoparticles and thereby selectively affect the diffusion properties in a barrier layer.

The protective action is also in this case adapted to the particular application through the combination among the at least four possible effects: diffusion barrier, electrochemical effect, hydrophobic surface and an, if applicable, germicidally acting surface.

In the working processes of materials the workpieces are often contaminated and must subsequently be re-cleaned. This residual contamination is especially disadvantageous if the dirt particles adhere well to the workpiece surface. Here the setting of the contact angle of the workpiece with respect to the contaminating medium is especially important and, in the case of metals, is in the range of >120°.

The rapid and complete removal of deposits on the material surfaces is therefore optimized through a custom-tailored behavior (hydrophobic or hydrophilic). Applications in the pharmaceutical field such as for example the cleaning or the contamination repulsion from the package outside as well as the residual emptying of the package content are of particular interest.

1. Method for the production of a workpiece surface (9) with predeterminable hydrophobic behavior with a water contact angle (WCA) greater than 90° comprising the following steps:
a) a substrate (1) is utilized into which, at least in subregions, a line-like or grid-like microstructure (2, 3) with indentations or elevations (2) is mechanically embossed, which microstructure is formed of a multiplicity of contiguous structure elements (3), whose individual extents (1, 1′) are in the range of 3 μm to 50 μm, and that between the adjoining structure elements (3) trough-shaped indentation or elevations (2) with a depth in the range of 1 μm to 10 μm, preferably 3 μm to 7 μm, are formed, which are disposed about the structure elements (3) with a width in the range of 3 μm to 11 μm;
b) In a further step at least one cover layer (7) is deposited in a vacuum chamber (20) out of a plasma discharge, at least in subregions onto the substrate (1), which plasma discharge comprises at least one metal-containing and one oxygen-containing gas and/or a metal oxide-containing compound and has a layer thickness in the range of 5.0 to 500 nm.

2. Method for the production of a polymeric workpiece surface (9) with predeterminable hydrophobic behavior with a water contact angle (WCA) greater than 90° as well as a germicidally acting workpiece surface comprising the following steps:
a) a substrate (1) is utilized which is at least one the surface (4) comprised of a synthetic material (1a) and into this synthetic material surface (4), at least in subsregions, a line-like or grid-like microstructure (2, 3) with indentations or elevations (2) is mechanically embossed, which microstructure is formed of a multiplicity of contiguous structure elements (3), whose individual extents (1, 1′) are in the range of 3 μm to 50 μm, and that between the adjoining structure elements (3) trough-shaped indentation or elevations (2) with a depth in the range of 1 μm to 10 μm are formed, which are disposed about the structure elements (3) with a width in the range of 3 μm to 11 μm;
b) after the mechanical structuring the substrate (1) is treated in a vacuum chamber (20) in at least two steps with a plasma discharge, at least in subregions, wherein in a first step to the plasma at least oxygen or hydrogen is supplied for the chemical etching of the substrate surface (4) and, in a succeeding second step, to the plasma at least one inert gas is added for the ion etching of the substrate surface (4);
c) after the plasma treatment a hydrocarbon-containing protective layer (6) is deposited in a vacuum chamber (20) out of a plasma discharge, at least in subregions, onto the substrate (1), to which plasma discharge is supplied at least one hydrocarbon-containing gas and that a layer thickness is generated which is in the range of 2.0 nm to 70 nm;
d) in a further step at least one cover layer (7) is deposited in a vacuum chamber (20) out of a plasma discharge, at least in subregions, onto the substrate (1), which plasma discharge comprises at least one metal-containing and one oxygen-containing gas and/or a metal oxide-containing compound and has a layer thickness in the range of 5.0 to 100 nm.

3. Method for the production of a workpiece surface (9) with predeterminable hydrophobic behavior with a water contact angle (WCA) greater than 90°, comprising the following steps:
a) a substrate (1) is utilized into which, at least in subsregions, a line-like or grid-like microstructure (2, 3) with indentations or elevations (2) is mechanically embossed, which microstructure is formed of a multiplicity of contiguous structure elements (3), whose individual extents (1, 1′) are in the range of 3 μm to 50 μm, and that between the adjoining structure elements (3) trough-shaped indentation or elevations (2) with a depth in the range of 1 μm to 10 μm are formed, which are disposed about the structure elements (3) with a width in the range from 3 μm to 11 μm;
b) after the mechanical structuring a hydrocarbon-containing protective layer (6) is deposited in a vacuum chamber (20) out of a plasma discharge, at least in subregions, onto the substrate (1) onto the substrate (1), to which plasma discharge a hydrocarbon-containing gas is supplied, and that a layer thickness is generated which is in the range of 2.0 nm to 500 nm;
c) in a further step at least one cover layer (7) is deposited in a vacuum chamber (20) out of a plasma discharge, at least in subregions, onto the substrate (1), to which plasma discharge is supplied a metal-containing and oxygen-containing gas and/or a metal oxide-containing compound, and that a layer thickness is generated which is in the range of 5.0 nm to 500 nm;
d) in a further step at least one type of metal-containing nanoparticles (8) is deposited in a vacuum chamber (20) out of a plasma discharge, at least in subregions, onto the substrate (1), to which plasma discharge is supplied at least one metal-containing gas, and that these nanoparticles have a particle size of 1.0 to 70 nm diameter.

4. Method as claimed in claim 1, characterized in that the outer surface (9)—in particular the topmost atom layers of the cover layer (7)—are provided with at least one type of metal-containing nanoparticles (8) according to the plasma treatment (3d) of the substrate (1), and that these particles have a particle size of 1.0 to 70 nm diameter.

5. Method as claimed in claim 1, characterized in that the cover layer (7) is comprised of a catalytically active metal oxide from the series TiO₂ and ZnO.

6. Method as claimed in claim 1, characterized in that into the outer surface (9) of the cover layer (7) is incorporated with at least one type of metal-containing nanoparticles (8) according to plasma treatment (3d) of the substrate (1), from the series Ag, Au, Pt, Pd, Rh, Cu, Fe, Zn, Ti.

7. Method as claimed in claim 1, characterized in that the outer surface (9)—in particular the topmost atom layers of the cover layer (7)—are provided with at least one type of metal-containing nanoparticles (8) according to the plasma treatment (3d) of the substrate (1) at 5 to 50 at %, preferably at 5 to 20 at %.

8. Method as claimed in claim 1, characterized in that a hydrocarbon-containing adhesion-promoting protective layer (6) is deposited beneath the cover layer (7) in a vacuum chamber (20) out of a plasma discharge, at least in subregions, onto the substrate (1), to which plasma discharge at least one hydrocarbon-containing gas is supplied and that a layer thickness is generated which is in the range of 2.0 to 500 nm.

9. Method as claimed in claim 1, characterized in that a silicon oxide-containing protective layer (6) is deposited beneath the cover layer (7) in a vacuum chamber (20) out of a plasma discharge, at least in subregions, onto the substrate (1), to which plasma discharge is supplied at least one silicon-containing and at least one oxygen-containing gas, and that a layer thickness is generated, which is in the range of 2.0 nm to 500 nm.

10. Method as claimed in claim 1, characterized in that the hydrocarbon-containing, adhesion-promoting protective layer (6) is provided, at least in subregions, with at least one type of metal-containing nanoparticles (11) in the range of 5 to 50 at %, preferably of 5 to 20 at %.

11. Method as claimed in claim 1, characterized in that as the substrate (1) a synthetic material or a metal is utilized, preferably a ductile synthetic material, a ductile metal or a metallically coated ductile synthetic material.

12. Method as claimed in claim 1, characterized in that the protective layer (6) is deposited at a thickness in the range of 2.0 nm to 50 nm.

13. Method as claimed in claim 1, characterized in that as the synthetic material of the substrate (1) a thermoplastic resin, preferably polypropylene, is utilized.

14. Method as claimed in claim 1, characterized in that the line-like or grid-like microstructure (2, 3) is generated of periodically repeating, like structure elements (3), preferably through mechanical embossing.

15. Method as claimed in claim 1, characterized in that the microstructure (2, 3) is generated using a hot embossing method.

16. Method as claimed in claim 1, characterized in that for the substrate (1) a band is utilized, preferably a foil or film, a membrane, a textile and/or a fabric.

17. Method as claimed in claim 1, characterized in that for the substrate (1) a three-dimensional body is utilized, which is surface treated on the inside and/or the outside.

18. Method as claimed in claim 1, characterized in that the microstructured substrate (1), before the deposition of the protective layer (6), is cleaned in a vacuum chamber (20) with a plasma treatment thereby that preferably argon is supplied.

19. Method as claimed in claim 1, characterized in that with the plasma treatment (2b) with the two treatment steps, at least in subregions, of the substrate surface (4) a nanostructure (6′) is worked out with the dimensions of 40 to 200 nm and with structure heights in the range of 20 to 120 nm.

20. Method as claimed in claim 1, characterized in that on the treated surface (9) of the workpiece (10) a water contact angle is generated, which is in the range of 90° to 160°, preferably in the range of 110° to 160°.

21. Method as claimed in claim 1, characterized in that in the deposition of the protective layer (6) at least one metal-containing nanoparticle (11) is incorporated, which increases the corrosion protection of the metal-containing workpiece (10) or affects the diffusion properties of permeating compounds.

22. Workpiece comprising a substrate (1) structured and coated on the surface (4) on at least one side, characterized in that, at least in subregions, a microstructure (2, 3) with indentations or elevations (2) is mechanically embossed, which microstructure is formed of a multiplicity of contiguous structure elements (3) with individual extents in the range of 3 to 50 μm, and that between the adjoining structure elements (3) indentations or elevations are formed in the shape of troughs, which are disposed about the structure elements, and that onto the microstructure (2, 3), at least in subregions, is superimposed a hydrocarbon-containing or silicon-containing protective layer (6) with a layer thickness in the range of 2.0 to 500 nm, and that, at least in subregions, superjacent thereto a photocatalytically active titanium oxide-containing layer is disposed as a cover layer (7) with the outer surface (9), which is provided with metal-containing nanoparticles (8), and that the workpiece (10) on this surface (9) has a water contact angle >90°.

23. Workpiece comprising a substrate (1) structured and coated at least on one side on the surface (4), characterized in that, at least in subregions, a microstructure (2, 3) with indentations or elevations (2) is mechanically embossed, which is formed of a multiplicity of contiguous structure elements (3) with individual extents in the range of 3 to 50 μm, and that between the adjoining structure elements (3) indentations or elevations are formed in the shape of troughs, which are disposed about the structure elements, and superjacent thereto, at least in subregions, a protective layer (6) is deposited comprising at least one metal-containing nanoparticle (11), which protective layer represents a diffusion barrier with respect to the uncoated substrate (1), and that superjacent thereto, at least in subregions, at least one further layer as cover layer (7) is disposed with the outer surface (9) and that the workpiece on this surface (9) has a water contact angle >90°.
